(19) United States
(12) Patent Application Publication
(10) Pub. No.: US 2025/0125779 A1
(43) Pub. Date: Apr. 17, 2025

(54) CLASS-D AMPLIFIER DEVICE FOR HAPTIC APPLICATIONS

(71) Applicant: Microchip Technology Incorporated, Chandler, AZ (US)

(72) Inventor: Razvan Costache, Dambovita (RO)

(73) Assignee: Microchip Technology Incorporated, Chandler, AZ (US)

(21) Appl. No.: 18/631,132

(22) Filed: Apr. 10, 2024

Related U.S. Application Data
(60) Provisional application No. 63/543,859, filed on Oct. 12, 2023.

(51) Int. Cl. H03F 3/217; H10N 30/20

(52) U.S. Cl. CPC H03F 3/2171; H10N 30/20; H03F 2200/351

(57) ABSTRACT

An input signal may be converted into a first PWM signal and a second PWM signal at a PWM controller circuit. The first PWM signal and second signal output may drive a driver circuit. The driver circuit may receive a high-voltage supply from a boost converter or other power circuit. The driver circuit may include a high-side device and a low-side device. The output of the driver circuit may drive a filter circuit, the filter circuit comprising a filter capacitor, an inductor and a haptic actuator. The haptic actuator may produce a desired haptic response at the haptic actuator.

### PRIORITY

This application claims priority to commonly owned U.S. Provisional Patent Application No. 63/543,859 filed Oct. 12, 2023, the entire contents of which are hereby incorporated by reference for all purposes.

### FIELD OF THE INVENTION

The present disclosure relates to a class-D amplifier for haptic applications.

### BACKGROUND

A haptic driver may drive a haptic actuator with an electrical signal to produce a mechanical response. In a haptic application, applying signals of different voltages and frequencies may result in different mechanical responses. These different mechanical responses may be felt by a user as a button press, switch toggle or other physical responses. The use of haptic drivers and haptic actuators to generate physical responses may be termed haptics.

Haptics may be utilized to generate a vibration alert or other physical response in a mobile device, including but not limited to a cellular phone or a game controller. Haptics may be utilized in an automotive application as part of a steering wheel or console interface on a touchscreen.

In battery powered applications with haptic actuators with large capacitive loads, the system power consumption becomes an important factor. For example, driving arbitrary patterns on haptic actuators of large capacitance, at high voltages, from a Li-Ion battery becomes a challenge.

Portable haptic applications with large capacitive actuators, exceeding 1 uF in capacitance, need significant drive power at high voltage operation. Haptic actuators may require drive voltages in excess of 100V. Boosting such a drive voltage from a 4V battery input, after accounting for the power supply losses classic linear drive losses, results in very low efficiency and makes the approach unfeasible.

There is a need for a device which may drive haptic actuators with high voltages at improved efficiencies.

### SUMMARY

The examples herein enable systems and methods for driving a haptic actuator with a class-D amplifier.

According to one aspect, a class-D amplifier device includes a PWM controller circuit. The PWM controller circuit receives an input signal and generates a first PWM signal and a second PWM signal based on the input signal. The first PWM signal may be a fixed-frequency PWM signal and the second PWM signal may be a non-overlapped version of the first PWM signal. A first plate of a first coupling capacitor may be coupled to receive the first PWM signal and a first plate of a second coupling capacitor may be coupled to the receive the second PWM signal. A driver circuit may include a high-side device coupled to a second plate of the first coupling capacitor and a low-side device coupled to a second plate of the second coupling capacitor. The driver circuit may drive an output node. A filter circuit may be coupled to the output node, the filter circuit comprising: a filter capacitor, an inductor; and a haptic actuator. The filter capacitor includes a first plate coupled to the output node and a second plate coupled to a common node. The inductor includes a first node coupled to the output node, and a second node coupled to a first node of the haptic actuator. The second node of the haptic actuator may be coupled to a common node.

According to one aspect, a system includes a microcontroller to generate an input signal, the input signal to generate a haptic response at a haptic actuator. The system may include a PWM controller circuit. The PWM controller circuit may receive the input signal and may generate a first PWM signal and a second PWM signal based on the input signal. The first PWM signal may be a fixed-frequency PWM signal and the second PWM signal may be a non-overlapped version of the first PWM signal. A coupling circuit may couple the first PWM signal and second PWM signal to a driver circuit. The driver circuit may include a high-side device and a low-side device. The driver circuit may drive an output node. A filter circuit may be coupled to the output node, the filter circuit to filter the output node.

According to one aspect, a method includes steps of: receiving an input signal, the signal to produce a haptic response at a haptic actuator, converting the input signal to a first PWM signal and a second PWM signal, the first PWM signal comprising a fixed-frequency PWM signal and the second PWM signal an inverted and non-overlapped version of the first PWM signal, coupling the first PWM signal to a first coupling capacitor and coupling the second PWM signal to a second coupling capacitor, driving a driver circuit with the outputs of the first coupling capacitor and the second coupling capacitor, filtering the output of the driver circuit with a filter circuit.

### BRIEF DESCRIPTION OF THE DRAWINGS

FIG. 1 illustrates one of various examples of a class-D amplifier device for a haptic application.

FIG. 2 illustrates one of various examples of a timing diagram of first PWM signal and second PWM signal.

FIG. 3A illustrates another example of signal waveforms in a class-D amplifier device for a haptic application.

FIG. 3B illustrates another example of signal waveforms in a class-D amplifier device for a haptic application.

FIG. 3C illustrates another example of signal waveforms in a class-D amplifier device for a haptic application.

FIG. 4 illustrates another example of signal waveforms in a class-D amplifier device for a haptic application.

FIG. 5 illustrates a method of driving a haptic actuator with a class-D amplifier.

### DETAILED DESCRIPTION

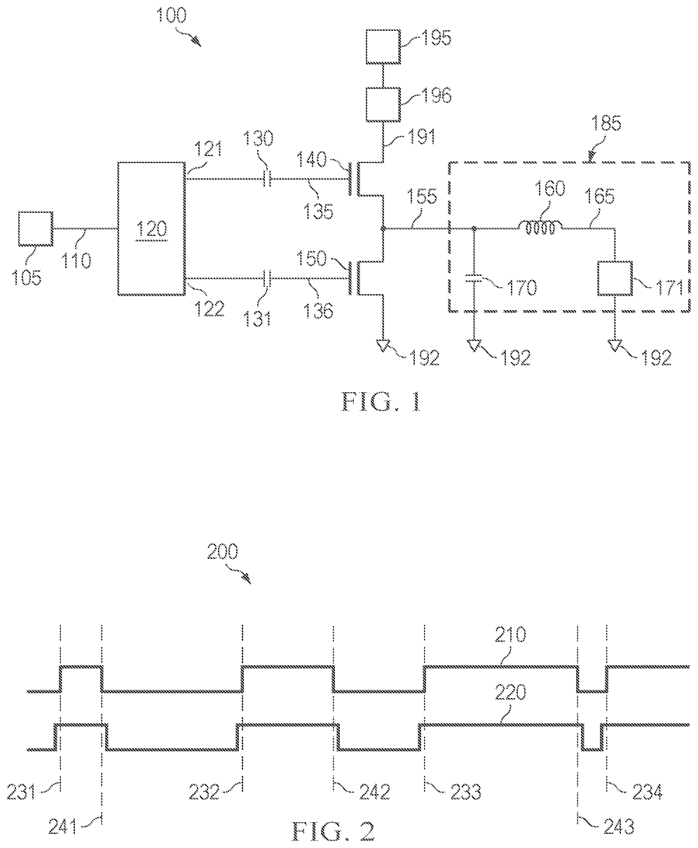

FIG. 1 illustrates one of various examples of a class-D amplifier device for a haptic application. A haptic application may be an electronic circuit including a haptic actuator. FIG. 1 illustrates a particular haptic application, but this is not intended to be limiting. Input signal 110 may be input to PWM controller circuit 120. Input signal 110 may be provided by microcontroller 105, an analog-to-digital converter (ADC), or another circuit not specifically mentioned. Input signal 110 may be a bursted sinusoidal signal of a fixed frequency, or may be a bursted sinusoid of a variable frequency. Input signal 110 may be a square-wave signal, a triangular signal, a trapezoidal signal, or another signal not specifically mentioned. The frequency and amplitude of input signal 110 may be selected to generate a specific haptic response.

PWM controller circuit 120 may convert input signal 110 into two PWM signals comprising a first PWM signal 121 and a second PWM signal 122. First PWM signal 121 may be a fixed-frequency PWM signal. Second PWM signal 122 may be a phase shifted version of first PWM signal 121 and may have a shorter ON time than first PWM signal 121. First PWM signal 121 and second PWM signal 122 may be non-overlapping PWM signals. Second PWM signal 122 may be an inverted and non-overlapped version of first PWM signal 121.

First PWM signal 121 may be communicatively coupled to a first plate of first coupling capacitor 130. Second PWM signal 122 may be communicatively coupled to a first plate of second coupling capacitor 131. First coupling capacitor 130 and second coupling capacitor 131 may comprise a coupling circuit and may couple the first PWM signal and the second PWM signal to a driver circuit.

A second plate of first coupling capacitor 130 may provide high-side drive signal 135. High-side drive signal 135 may be coupled to a first node of high-side device 140. A second node of high-side device 140 may be coupled to a supply voltage 191. A third node of high-side device 140 may be coupled to output node 155. In one of various examples, high-side device 140 may be a metal-oxide semiconductor field-effect (MOSFET) device, particularly a p-channel MOSFET (PFET), and the first node of high-side device 140 may comprise a gate node, the second node of high-side device may comprise a source node, and the third node of high-side device 140 may comprise a drain node. High-side device 140 and low-side device 150 may comprise the driver circuit.

In one of various examples, supply voltage 191 may be generated by boost converter 196. Boost converter 196 may receive input from battery 195. In one of various examples, battery 195 may be a single-cell lithium-ion battery with a nominal voltage of 3.7V, but this is not intended to be limiting. In one of various examples, supply voltage 191 may be a high-voltage supply exceeding 100 volts, the high-voltage supply generated by boost converter 196.

The second plate of second coupling capacitor 131 may provide low-side drive signal 136. Low-side drive signal 136 may be communicatively coupled to a first node of low-side device 150. A second node of low-side device 150 may be coupled to a common node 192. In one of various examples, common node 192 may be a ground node. A third node of low-side device 150 may be coupled to output node 155. In one of various examples, low-side device 150 may be a metal-oxide semiconductor field-effect (MOSFET) device, particularly an n-channel MOSFET (NFET), and the first node of low-side device 150 may comprise a gate node, the second node of low-side device 150 may comprise a source node, and the third node of low-side device 150 may comprise a drain node.

Output node 155 may be coupled to a first node of inductor 160 and to a first plate of filter capacitor 170. A second plate of filter capacitor 170 may be coupled to common node 192. Common node 192 may be a ground node. A second node of inductor 160 may provide haptic drive signal 165. Haptic drive signal 165 may be coupled to a first lead of haptic actuator 171. Haptic actuator 171 may be a piezoelectric actuator, or another type of haptic actuator not specifically mentioned. Haptic actuator 171 may be coupled to common node 192.

Filter capacitor 170, inductor 160 and haptic actuator 171 may, taken together, comprise a filter circuit 185. Filter capacitor 170, inductor 160 and haptic actuator 171 may comprise a PI filter circuit based on the configuration of inductor 160 coupled between filter capacitor 170 and haptic actuator 171, which haptic inductor 171 may be modelled as a capacitor.

In operation, input signal 110 may comprise a bursted signal to generate a specific haptic response. Input signal 110 may be a specific frequency, specific amplitude and specific duration to generate a particular haptic response. PWM controller circuit 120 may generate first PWM signal 121 and second PWM signal 122 to drive, respectively, a first plate of first coupling capacitor 130 and a first plate of second coupling capacitor 131. The second plate of first coupling capacitor 130 may provide high-side drive signal 135 to drive high-side device 140, and the second plate of second coupling capacitor 131 may provide low-side drive signal 136 to drive low-side device 150. Output node 155 may comprise a high-voltage representation of input signal 110. Inductor 160, filter capacitor 170 and haptic actuator 171 may form a low-pass filter, as haptic actuator 171 may be modelled as a capacitor. Haptic actuator 171 thus comprises part of the low-pass filter. In this manner, the haptic actuator 171 may be driven with a low-pass signal and may generate a desired low-frequency haptic response. Use of the PI filter structure may reduce current consumption in class-D amplifier device 100 when generating high voltages at boost converter 196.

FIG. 2 illustrates one of various examples of a timing diagram 200 of first PWM signal 121 and second PWM signal 122.

Trace 210 may be one of various examples of first PWM signal 121. Trace 210 may be a fixed-frequency PWM signal. The ON-time of trace 210 may be modulated based on the value of the input signal. The ON-time of signal may be defined as the duration of time the signal is at a logic high level. At location 231, trace 210 may represent a signal with a large amplitude, and at location 234, trace 210 may represent a signal with a small amplitude.

Trace 220 may be one of various examples of second PWM signal 122. First PWM signal 121 and second PWM signal 122 may be non-overlapping signals, such that first PWM signal 121 and second PWM signal 122 transition at different times. The ON-time of trace 210 may be modulated based on the value of the input signal. At location 231, trace 210 may represent a signal with a small amplitude, and at location 234, trace 210 may represent a signal with a large amplitude.

Trace 210 may include a rising edge transition at location 231. Trace 220 may include a rising edge transition prior to time 231. Trace 210 may include a falling edge transition at location 241. Trace 220 may include a falling edge transition after time 241. In this manner, trace 220 may include a larger ON-time than trace 210, where ON-time is defined as the time a signal is in a logic high state, though this is not intended to be limiting.

Trace 210 may include a rising edge transition at location 232. Trace 220 may include a rising edge transition prior to time 232. Trace 210 may include a falling edge transition at location 242. Trace 220 may include a falling edge transition after time 242. In this manner, trace 220 may include a larger ON-time than trace 210.

Trace 210 may include a rising edge transition at location 233. Trace 220 may include a rising edge transition prior to time 233. Trace 210 may include a falling edge transition at location 243. Trace 220 may include a falling edge transition after time 243. In this manner, trace 220 may include a larger ON-time than trace 210. Trace 210 may include a rising edge transition at location 234. Trace 220 may include a rising edge transition prior to time 234.

The example of FIG. 2 is for illustrative purposes only and should not be interpreted as limiting the invention to the specific ON-times or duty cycles illustrated in FIG. 2.

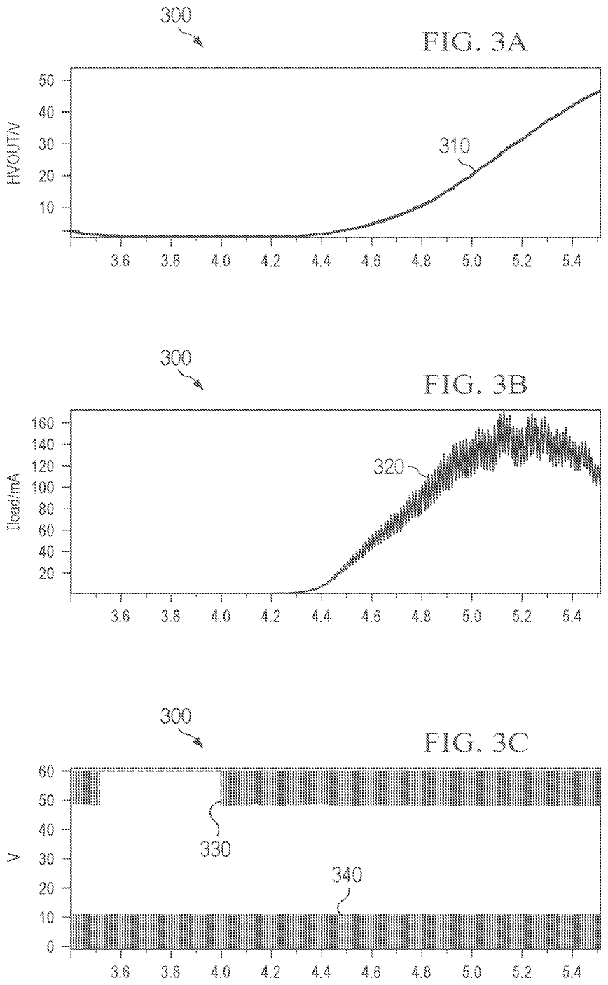

FIG. 3A illustrates another example of signal waveforms in a class-D amplifier device for a haptic application.

As illustrated in FIG. 3A, trace 310 may represent one of various examples of haptic drive signal 165 for driving haptic actuator 171 as described and illustrated in reference to FIG. 1. As illustrated in FIG. 3A, trace 310 may represent a low-pass filtered version of traces 330 and 340 of FIG. 3C and may drive a haptic actuator with a low-pass signal to produce a desired haptic response.

FIG. 3B illustrates another example of signal waveforms in a class-D amplifier device for a haptic application. As illustrated in FIG. 3B, trace 320 may represent one of various examples of current consumption of the class-D amplifier device. The current consumption of the class-D amplifier device may include the current flowing through high-side device 140 and low-side device 150 and current flowing to haptic actuator 171, as described and illustrated in reference to FIG. 1.

FIG. 3C illustrates another example of signal waveforms in a class-D amplifier device for a haptic application. As illustrated in FIG. 3C, traces 330 and 340 may drive, respectively, drive signals to a low-side device drive and a high-side device. Trace 330 may represent one of various examples of low-side drive signal 136 as described and illustrated in reference to FIG. 1. Trace 340 may represent one of various examples of high-side drive signal 135 as described and illustrated in reference to FIG. 1. The duty cycle of traces 330 and 340 may modulate to produce varying amplitudes at trace 310.

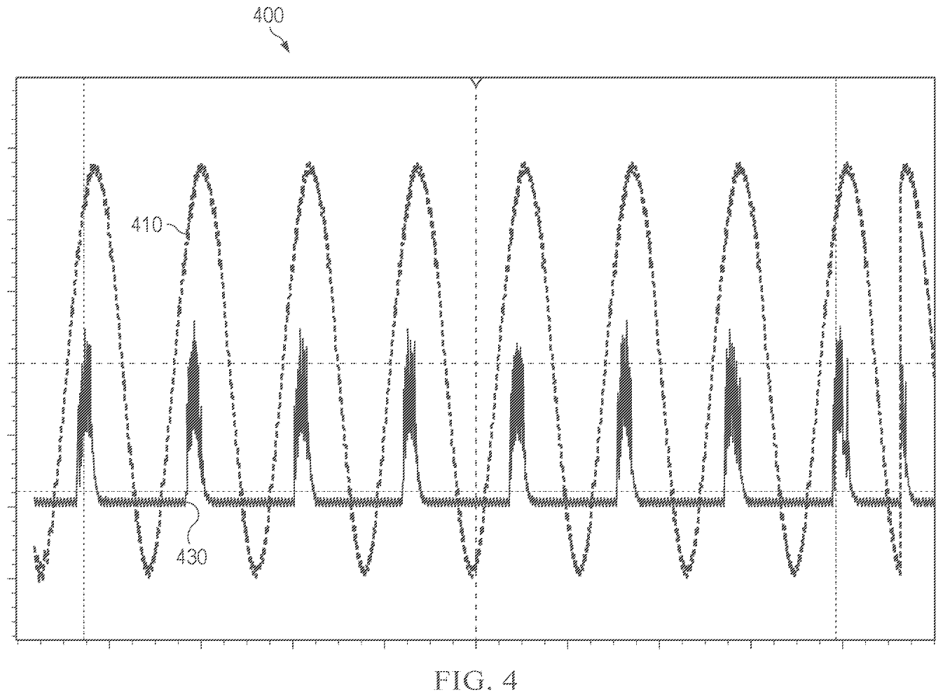

FIG. 4 illustrates another example of signal waveforms 400 in a class-D amplifier device for a haptic application.

Trace 410 may represent one of various examples of haptic drive signal 165, as described and illustrated in reference to FIG. 1. A filter circuit, as described in reference to FIG. 1, may filter an input signal and may produce the low-pass filtered signal as illustrated in trace 410.

Trace 430 may represent the current consumption of the class-D amplifier device including a haptic actuator as part of a PI filter. The use of a PI filter comprising filter capacitor 170, inductor 160 and haptic actuator 171 may reduce the current consumption of the class-D amplifier device.

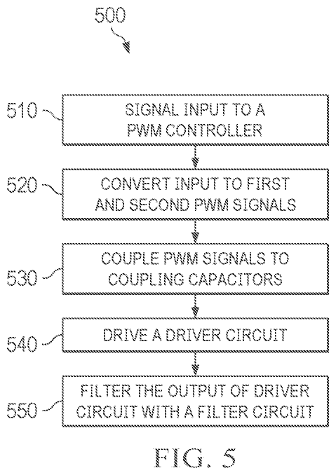

FIG. 5 illustrates a method of driving a haptic actuator. At operation 510, an input signal may be input to a PWM controller circuit. The input signal may be a specific frequency, amplitude and duration in order to produce a specific haptic response at a haptic actuator. The input signal may be provided by a microcontroller.

At operation 520, the PWM controller circuit may convert the input signal to a first PWM signal and a second PWM signal. At operation 530, the first PWM signal may be coupled to a first plate of a first coupling capacitor, and the second PWM signal may be coupled to a first plate of a second coupling capacitor.

At operation 540, the second plate of the first coupling capacitor and the second plate of the second coupling capacitor may drive a driver circuit. The driver circuit may comprise a high-side device and a low-side device.

At operation 550, the output of the driver circuit may be filtered by a filter circuit, the filter circuit including a haptic actuator.

1. A class-D amplifier device comprising:
a PWM controller circuit, the PWM controller circuit to receive an input signal and to generate a first PWM signal and a second PWM signal based on the input signal, the first PWM signal comprising a fixed-frequency PWM signal and the second PWM signal a non-overlapped version of the first PWM signal;
a first plate of a first coupling capacitor coupled to receive the first PWM signal;
a first plate of a second coupling capacitor coupled to the receive the second PWM signal;
a driver circuit comprising a high-side device coupled to a second plate of the first coupling capacitor and a low-side device coupled to a second plate of the second coupling capacitor, the driver circuit to drive an output node, and
a filter circuit coupled to the output node, the filter circuit comprising:
a filter capacitor;
an inductor; and
a haptic actuator;
wherein the filter capacitor comprises a first plate coupled to the output node and a second plate coupled to a common node, the inductor comprises a first node coupled to the output node, and a second node coupled to a first node of the haptic actuator, and the second node of the haptic actuator coupled to a common node.

2. The device as claimed in claim 1, the high-side device comprising a metal-oxide semiconductor field-effect device (MOSFET).

3. The device as claimed in claim 1, the low-side device comprising a metal-oxide semiconductor field-effect device (MOSFET).

4. The device as claimed in claim 1, the high-side device to receive a supply voltage from a boost converter, the boost converter to convert a battery voltage to a high-voltage supply, the high-voltage supply greater than or equal to 10 Volts.

5. The device as claimed in claim 1, the input signal comprising a bursted sinusoidal signal, the bursted sinusoidal signal based on a desired haptic response.

6. The device as claimed in claim 1, the haptic actuator comprising a piezoelectric actuator.

7. A system comprising:
a microcontroller to generate an input signal, the input signal to generate a haptic response at a haptic actuator;
a PWM controller circuit, the PWM controller circuit to receive the input signal and to generate a first PWM signal and a second PWM signal based on the input signal, the first PWM signal comprising a fixed-frequency PWM signal and the second PWM signal a non-overlapped version of the first PWM signal;
a coupling circuit to couple the first PWM signal and second PWM signal to a driver circuit, the driver circuit comprising a high-side device and a low-side device, and the driver circuit to drive an output node, and
a filter circuit communicatively coupled to the output node, the filter circuit to filter the output node.

8. The system as claimed in claim 7, the coupling circuit comprising a first coupling capacitor coupled between the first PWM signal and the high-side device and comprising a second coupling capacitor coupled between the second PWM signal and the low-side device.

9. The system as claimed in claim 7, the input signal comprising a bursted sinusoidal signal, the bursted sinusoidal signal based on a desired haptic response.

10. The system as claimed in claim 7, the haptic actuator comprising a piezoelectric actuator.

11. The system as claimed in claim 7, the driver circuit to receive a supply voltage from a boost converter.

12. A method comprising:
receiving an input signal, the signal to produce a haptic response at a haptic actuator;
converting the input signal to a first PWM signal and a second PWM signal, the first PWM signal comprising a fixed-frequency PWM signal and the second PWM signal an inverted and non-overlapped version of the first PWM signal;
coupling the first PWM signal to a first coupling capacitor and coupling the second PWM signal to a second coupling capacitor;
driving a driver circuit with the outputs of the first coupling capacitor and the second coupling capacitor;
filtering the output of the driver circuit with a filter circuit.

13. The method as claimed in claim 12, the input signal comprising a bursted sinusoidal signal, the bursted sinusoidal signal based on a desired haptic response.

14. The method as claimed in claim 12, the driver circuit comprising a high-side device and a low-side device.

15. The method as claimed in claim 14, the high-side device to receive a power supply voltage from a boost converter.

16. The method as claimed in claim 12, the haptic actuator comprising a piezoelectric actuator.
